(19) United States
(12) Patent Application Publication
(10) Pub. No.: US 2024/0363994 A1
(43) Pub. Date: Oct. 31, 2024

(54) ANTENNA DEVICE AND METHOD OF MANUFACTURING ANTENNA DEVICE

(71) Applicant: SHUNSIN TECHNOLOGY (ZHONG SHAN) LIMITED, Zhongshan (CN)

(72) Inventor: SHUN-HSING LIAO, Zhongshan City (CN)

(21) Appl. No.: 18/225,711

(22) Filed: Jul. 25, 2023

(30) Foreign Application Priority Data
Apr. 28, 2023 (CN) 202310485128.0

(51) Int. Cl. H01Q 1/22; H01L 21/56; H01L 21/60; H01L 23/00; H01L 23/498; H01L 23/66; H01Q 1/38; H01Q 9/04

(52) U.S. Cl. CPC H01Q 1/2283; H01L 21/56; H01L 21/60; H01L 23/49816; H01L 23/66; H01L 24/08; H01L 24/13; H01L 24/16; H01Q 1/38; H01Q 9/0414; H01L 2021/60262; H01L 2223/6677; H01L 2224/08112; H01L 2224/08113; H01L 2224/12105; H01L 2224/13023; H01L 2224/16113

(57) ABSTRACT

An antenna device and a method of manufacturing the antenna device are provided. The antenna device includes a circuit board, a chip, an encapsulation layer, and an antenna. The circuit board includes an insulation substrate having an upper surface, a lower surface, and a groove formed on the upper surface; a conductive circuit disposed in the insulation substrate; a first conductive pad disposed in the insulation substrate, connected to the conductive circuit, and exposed from the lower surface; a second conductive pad connected to the conductive circuit, and exposed from the groove; and a third conductive pad exposed from the groove. The chip is disposed in the groove, connected to the second conductive pad, and coupled to the third conductive pad. The encapsulation layer is disposed in the groove, and covers the chip.

### FIELD

The subject matter herein generally relates to thin antenna devices.

### BACKGROUND

Due to the increasing demand for miniaturization of communication devices, the package size of the antenna device is required to be reduced as much as possible to meet the requirements of use. In the conventional art, the antenna structure and the communication chip are arranged on two opposite sides of a circuit board, and then another switching circuit board is used to electrically connect the communication chip and the electronic device. Therefore, the thickness of the antenna device is difficult to further reduce, so it is necessary to provide an improved solution for the antenna device to meet the requirements for the size of the antenna device.

### BRIEF DESCRIPTION OF THE DRAWINGS

Many aspects of the present disclosure are better understood with reference to the following drawings. The components in the drawings are not necessarily drawn to scale, the emphasis instead being placed upon clearly illustrating the principles of the present disclosure. It will be appreciated that for simplicity and clarity of illustration, where appropriate, reference numerals have been repeated among the different figures to indicate corresponding or analogous elements.

FIG. 1 is a schematic diagram of an antenna device in accordance with a first embodiment of the present application.

FIG. 2 is a schematic diagram of an antenna device in accordance with a second embodiment of the present application.

FIG. 3 to FIG. 5 are schematic diagrams of the semiconductor package device 1 in the manufacturing process in accordance with the embodiments of the present application.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The disclosure is illustrated by way of embodiments and not by way of limitation in the figures of the accompanying drawings, in which like references indicate similar elements. It should be noted that references to “an” or “one” embodiment in this disclosure are not necessarily to the same embodiment, and such references mean “at least one.”

The terms “connect” and “couple” are defined as directly or indirectly through intervening components, and are not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series, and the like.

In the present disclosure, a single circuit board is used to achieve the packaging structure of the antenna device, thereby reducing the thickness of the antenna device.

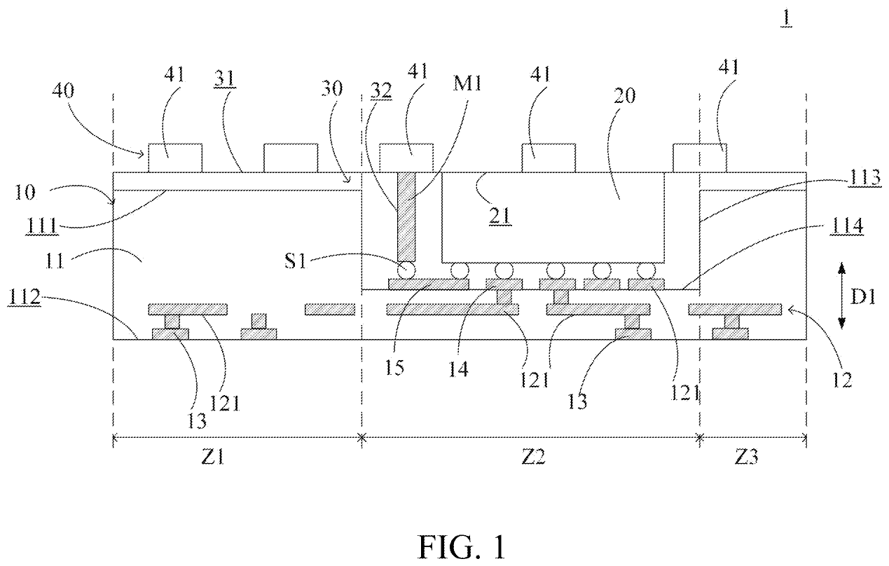

FIG. 1 is a schematic diagram of an antenna device 1 in accordance with a first embodiment of the present disclosure. As shown in FIG. 1, the antenna device 1 includes a circuit board 10, a chip 20, an encapsulation layer 30, and an antenna 40. The circuit board 10 includes an insulation substrate 11, a conductive circuit 12, first conductive pads 13, second conductive pads 14, and third conductive pads 15. The insulation substrate 11 extends perpendicular to a stacking direction D1. The insulation substrate 11 has an upper surface 111, a lower surface 112, and a groove 113 formed on the upper surface 111.

The conductive circuit 12 is disposed in the insulation substrate 11. The conductive circuit 12 extends in the stacking direction D1 or perpendicular to the stacking direction D1, and is distributed in insulation substrate 11. The conductive circuit 12 includes separate wires 121 respectively connected to the first conductive pads 13, the second conductive pads 14 and/or the third conductive pads 15.

The first conductive pads 13 are disposed in the insulation substrate 11, connected to the wires 121 of the conductive circuit 12, and exposed from the lower surface 112. The second conductive pads 14 are connected to the conductive circuit 12, and exposed from the groove 113. The third conductive pads 15 are exposed from the groove 113. In the embodiment, the second conductive pads 14 and the third conductive pads 15 are in the groove 113, and disposed on a bottom surface 114 of the groove 113.

In another embodiment, the second conductive pads 14 and/or the third conductive pads 15 are embedded in the insulation substrate 11, and exposed from the bottom surface 114 of the groove 113. In other words, the top surfaces of the second conductive pads 14 and/or the third conductive pads 15 and the bottom surface 114 of the groove 113 are formed as a flat plane. Alternatively, the top surfaces of the second conductive pads 14 and/or the third conductive pads 15 is lower than the bottom surface 114 of the groove 113 relative to the lower surface 112.

The formation of the circuit layer 10 may involve multiple deposition or coating processes, patterning processes, and planarization processes. The insulation substrate 11, the conductive circuit 12, the first conductive pads 13, the second conductive pads 14, and the third conductive pads 15 can be formed by deposition or coating processes. The deposition or coating processes may include a spin coating process, an electroplating process, an electroless process, a chemical vapor deposition (CVD) process, a physical vapor deposition (PVD) process, an atomic layer deposition (ALD) process, and other applicable processes and combinations thereof. The patterning process can be used to pattern the formed the insulation substrate 11, the conductive circuit 12, the first conductive pads 13, the second conductive pads 14, and the third conductive pads 15.

The patterning process may include a photolithography process, an energy beam drilling process (for example, a laser beam drilling process, an ion beam drilling process, or an electron beam drilling process), an etching process, a mechanical drilling process, or other applicable processes and combinations. The planarization process can be used to provide a flat top surface for the formed the insulation substrate 11, the conductive circuit 12, the first conductive pads 13, the second conductive pads 14, and the third conductive pads 15 to facilitate subsequent processes. The planarization process may comprise a mechanical polishing process, a chemical mechanical polishing (CMP) process, or other applicable process and combinations thereof.

In addition, the circuit layer 10 can also be formed by an additive buildup process. The additive buildup process may include the alternating stacking of one or more dielectric layers and conductive patterns or traces of the circuit layer 10. The conductive patterns or traces fan out across the occupied space of the electronic device, or are in a fan-shaped layout allowing the electrical traces into the occupied space of the electronic device. The conductive patterns can be formed by a plating process such as an electroplating process or an electroless plating process. The conductive pattern may comprise a conductive material, such as copper or other metals. The dielectric layer of the circuit layer 10 can be made of a photo-definable organic dielectric such as polyimide (PI), benzocyclobutene (BCB), or polybenzoxazole (PBO). In other embodiments, the dielectric material of the redistribution layer 12 may also be an inorganic dielectric layer. The inorganic dielectric layer may comprise silicon nitride (Si3N4), silicon oxide (SiO2), or SiON. The inorganic dielectric layer can be formed by growing an inorganic dielectric layer using an oxidation or nitridation process.

The chip 20 is coupled to the second conductive pads 14. In the embodiment, the chip 20 is directly connected to the third conductive pads 15. In another embodiment, the chip 20 is coupled to the third conductive pads 15 via the second conductive pads 14 and the conductive circuit 12. In the embodiment, in the stacking direction D1, the chip 20 can protrude over the groove 113 or the upper surface 111 of the insulation substrate 11. In another embodiment, in the stacking direction D1, the chip 20 does not protrude over the groove 113 or the upper surface 111 of the insulation substrate 11. In addition, the width of the groove 113 is greater than the width of the chip 20. In one embodiment, the width of groove 113 is in a range from 1.05 times to 1.3 times the width of chip 20. The width of the groove 113 and the width of the chip 20 is measured in a direction perpendicular to the stacking direction D1.

The chip 20 may be a semiconductor chip. In the embodiment, the chip 20 is a communication chip 20. Alternately, the chip 20 is a radio frequency (RF) transceiver. The chip 20 is disposed in the groove 113, and connected to the second conductive pads 14. In another embodiment, the chip 20 may be an optoelectronic device, micro-electromechanical systems (MEMS), a power amplifier chip, a power management chip, a biological identification device, a microfluidic system, or a physical sensor that measures changes in heat, light levels, and pressure. Moreover, the chip 20 may be semiconductor chips, such as imaging sensor devices, light-emitting diodes (LEDs), solar cells, accelerators, gyroscopes, fingerprint readers, micro actuators, surface acoustic wave devices, or process sensors or ink printer heads, made by a wafer scale package (WSP) process. In another embodiment, the chip 20 may be an imaging sensor device, a light-emitting diode (LED), a solar cell, an accelerator, a gyroscope, a fingerprint readers, a micro actuators, a surface acoustic wave devices, or a process sensor or an ink printer head, made by a wafer scale package (WSP) process.

The encapsulation layer 30 is disposed on the upper surface 111 of the insulation substrate 11 and filled in the groove 113. The encapsulation layer 30 covers the side surfaces of the chip 20. The encapsulation layer 30 an outer surface 31 and a hole 32. The hole 32 is formed on the outer surface 31, and penetrates through the encapsulation layer 30. The hole 32 communicates with the third conductive pad 15 and the antenna 40. In the embodiment, the antenna device 1 includes a solder ball S1 disposed on the third conductive pad 15. The conductive material M1 is filled in the hole 32, and connected to the solder ball S1 and the antenna 40.

In one embodiment, the encapsulation layer 40 may be an electromagnetic interference (EMI) shielding layer, configured to provide electromagnetic protection for chip 20. The materials of the encapsulation layer 30 include insulation materials and conductive materials. The insulation materials may include epoxy resin, cyanate resin, bismaleimide triazine, glass fiber, polybenzoxazole, polyimide, nitride (for example, silicon nitride), oxide (for example, silicon oxide), silicon oxynitride, or similar insulating materials, insulating organic material mixed with epoxy resin and glass fiber, or ceramic material. The conductive materials is distributed in the insulation materials, and may include materials such as metal sheets, metal powders, metal fibers or metalized fibers.

The top surface 21 of the chip 20 is exposed from the encapsulation layer 30. In the embodiment, the top surface 21 of the chip 20 and the outer surface 31 of the encapsulation layer 30 are formed as a flat plane. In another embodiment, the top surface 21 of the chip 20 is lower or higher than the outer surface 31 of the encapsulation layer 30 relative to the lower surface 112.

The antenna 40 is located over the insulation substrate 11, and connected to the third conductive pad 15 via the conductive material M1. The antenna 40 is arranged on a plane perpendicular to stacking direction D1, and is distributed on the upper surface 111 of the insulation substrate 11. The antenna 40 includes antenna structures 41. Two of the antenna structures 41 are connected to or separated from each other. In the embodiment, the antenna structures 41 are disposed on the encapsulation layer 30 and the top surface 21 of the chip 20. In another embodiment, in the stacking direction D1, the antenna structure 41 may not cover the top surface 21 of the chip 20. In another embodiment, in the stacking direction D1, the antenna structure 41 does not connected to the top surface 21 of the chip 20. In other words, the encapsulation layer 30 is between the antenna structure 41 and the top surface 21 of the chip 20.

As shown in FIG. 1, in a direction perpendicular to the stacking direction D1, the antenna device 1 has a first area Z1, a central area Z2, and a second area Z3. The central area Z2 is between the first area Z1 and the second area Z3. The groove 113, the second conductive pads 14, the third conductive pad 15, and the chip 20 are located in the central area Z2, and separated from the first area Z1 and the second area Z3. The antenna structure 41 is located in the first area Z1, the central area Z2, and the second area Z3. In another embodiment, the antenna structures 41 are separated from the central area Z2. In the embodiment, the encapsulation layer 30 is disposed in first area Z1 and the second area Z3, and the antenna structures 41 are disposed on the encapsulation layer 30 within the first area Z1 and the second area Z3.

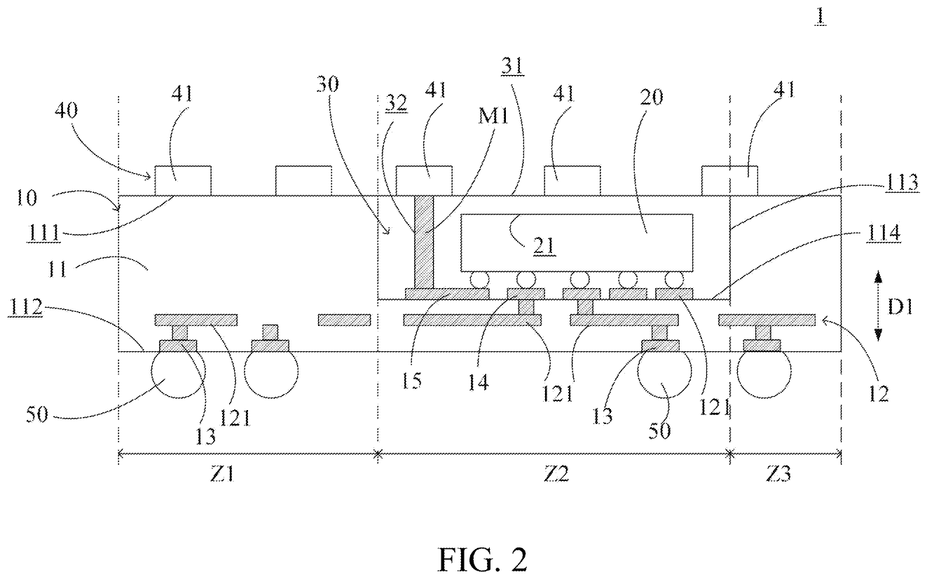

FIG. 2 is a schematic diagram of an antenna device 1 in accordance with a second embodiment of the present disclosure. In the second embodiment, conductive terminals 50 are disposed under the lower surface 112 of the circuit board 10, and respectively connected to first conductive pads 13. The conductive terminals 50 may be solder balls S1. In another embodiment, the conductive terminals 50 may be pins, but not limited thereto. For example, the conductive terminals 50 may be conductive balls, conductive pillars, conductive bumps, combinations thereof, or other forms and shapes formed by a ball-mounting process, an electroless plating process, or other suitable processes. According to the embodiments of the disclosure, a soldering process and a reflowing process can be performed to enhance adhesion between the conductive terminals 50 and the conductive pads 14.

In the second embodiment, the antenna device 1 may not include the solder balls S1. The hole 32 communicates with the third conductive pad 15, and the conductive material M1 is connected to the third conductive pad 15. The encapsulation layer 30 is filled in the groove 113. In the stacking direction D1, the encapsulation layer 30 covers the top surface 21 of the chip 20. The top surface 21 of the chip 20 is lower than the top opening of the groove 113 relative to the lower surface 112. In another embodiment, in the stacking direction D1, the encapsulation layer 30 does not cover the top surface 21 of the chip 20. The top surface 21 of the chip 20 contacts with or protrudes over the top opening of groove 113.

In the stacking direction D1, the encapsulation layer 30 does not cover the upper surface 111 of the insulation substrate 11. In other words, the encapsulation layer 30 is separated from the first area Z1 and the second area Z3, or does not disposed in the first area Z1 and the second area Z3. The antenna structure 41 is directly disposed on the upper surface 111 of the insulation substrate 11 in the first area Z1 and the second area Z3.

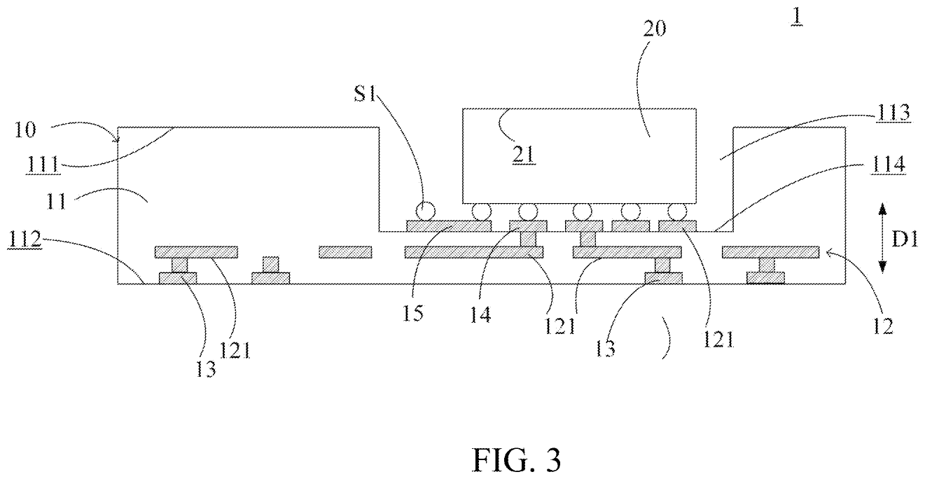

FIG. 3 to FIG. 5 are schematic diagrams of the semiconductor package device 1 in the manufacturing process in accordance with the embodiments of the present disclosure. As shown in FIG. 3, the groove 113 is formed on the upper surface 111 of the insulation substrate 11 of the circuit board 10. Next, the chip 20 is disposed in the groove 113, and connected to the second conductive pads 14. In the first embodiment, the solder ball S1 is disposed on the third conductive pad 15. The chip 20 is connected to the third conductive pad 15 via the solder ball S1. In the second embodiment, the antenna device 1 does not include the solder ball S1.

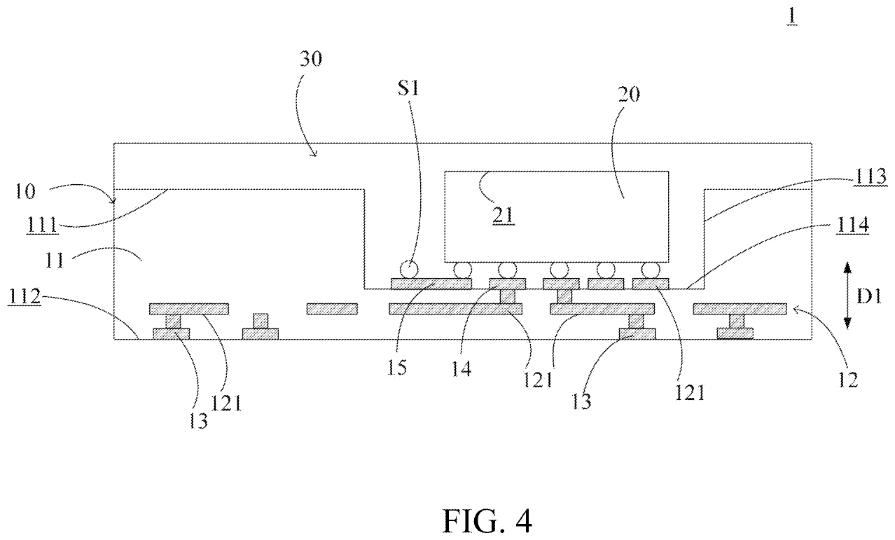

As shown in FIG. 4, the encapsulation layer 30 is formed in the groove 113, and covers the top surface 21 and the side surface of the chip 20. In the first embodiment, encapsulation layer 30 covers the upper surface 111 of the insulation substrate 11. In the second embodiment, the encapsulation layer 30 is filled in the groove 113. In the stacking direction D1, the encapsulation layer 30 does not cover the upper surface 111 of the insulation substrate 11. Moreover, in the stacking direction D1, the encapsulation layer 30 does not cover the top surface 21 of the chip 20.

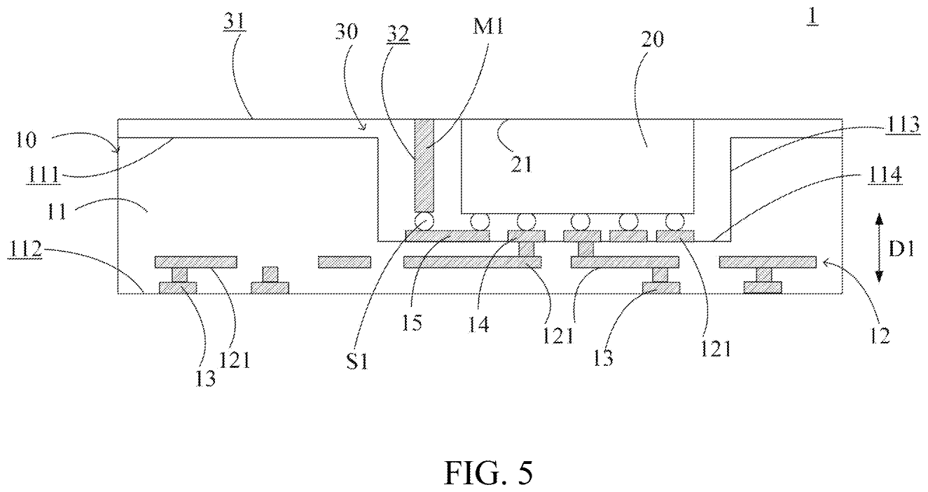

As shown in FIG. 5, the encapsulation layer 30 is polished to expose the top surface 21 of the chip 20 from the encapsulation layer 30. Next, the hole 32 is formed and communicates with the solder ball S1. Next, the conductive material M1 is filled in the hole 32, and connected to the solder ball S1. In the second embodiment, the encapsulation layer 30 is not polished. The hole 32 is formed and communicates with the third conductive pad 15. The conductive material M1 is filled in the hole 32, and connected to the third conductive pad 15.

Next, as shown in FIG. 1, the antenna 40 is disposed on the encapsulation layer 30 and connected to the conductive material M1. The antenna 40 can be disposed on the top surface 21 of the chip 20 and on the encapsulation layer 30. In the second embodiment, the antenna 40 is disposed on the upper surface 111 of the insulation substrate 11. Moreover, the antenna 40 may not be disposed on the top surface 21 of the chip 20. In the second embodiment, the antenna device 1 includes the conductive terminals 50.

According to the antenna device 1 in the embodiments of the present disclosure, the thickness of the antenna device 1 can be reduced by arranging the chip 20 in the groove 113 of the circuit board 10, so that the antenna device 1 can be well used on thin mobile devices.

Many details are often found in the relevant art, thus many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will, therefore, be appreciated that the embodiments described above may be modified within the scope of the claims.

What is claimed is:

1. An antenna device, comprising:
a circuit board comprising:
an insulation substrate having an upper surface, a lower surface, and a groove formed on the upper surface;
a conductive circuit disposed in the insulation substrate;
a first conductive pad disposed in the insulation substrate, connected to the conductive circuit, and exposed from the lower surface;
a second conductive pad connected to the conductive circuit, and exposed from the groove; and
a third conductive pad exposed from the groove;
a chip disposed in the groove, connected to the second conductive pad, and coupled to the third conductive pad;
an encapsulation layer disposed in the groove, and covering the chip; and
an antenna located over the insulation substrate, and connected to the third conductive pad via a conductive material.

2. The antenna device as claimed in claim 1, wherein the second conductive pad and the third conductive pad are in the groove, and disposed on a bottom surface of the groove.

3. The antenna device as claimed in claim 1, wherein the encapsulation layer has a hole communicating with the third conductive pad and the antenna, and the conductive material is filled in the hole, and connected to the third conductive pad and the antenna.

4. The antenna device as claimed in claim 1, wherein a top surface of the chip is exposed from the encapsulation layer.

5. The antenna device as claimed in claim 4, wherein the antenna is disposed on the top surface of the chip.

6. The antenna device as claimed in claim 1, wherein the antenna is disposed on the encapsulation layer.

7. A method of manufacturing an antenna device, comprising:
forming a groove on an upper surface of an insulation substrate of a circuit board, wherein the circuit board is provided with a conductive circuit disposed in the insulation substrate; a first conductive pad disposed in the insulation substrate, connected to the conductive circuit, and exposed from a lower surface of the insulation substrate; a second conductive pad connected to the conductive circuit, and exposed from the groove; and a third conductive pad exposed from the groove;
disposing a chip in the groove, the chip is connected to the second conductive pad, and coupled to the third conductive pad;
forming an encapsulation layer in the groove, and covering the chip;
forming a hole on the encapsulation layer to connect to the third conductive pad, and filling a conductive material in the hole, and the conductive material connected to the third conductive pad; and
disposing an antenna connected to the conductive material.

8. The method as claimed in claim 7, further comprising polishing the encapsulation layer to expose a top surface of the chip from the encapsulation layer.

9. The method as claimed in claim 8, further comprising disposing the antenna on the top surface of the chip.

10. The method as claimed in claim 7, further comprising disposing the antenna on the encapsulation layer.
